(19) United States
(12) Patent Application Publication
(10) Pub. No.: US 2022/0201877 A1
(43) Pub. Date: Jun. 23, 2022

(54) HOUSING AND METHOD FOR PROCESSING A HOUSING

(71) Applicant: SHENZHENSHI YUZHAN PRECISION TECHNOLOGY CO., LTD., Shenzhen (CN)

(72) Inventor: GANG WANG, Shenzhen (CN)

(21) Appl. No.: 17/555,428

(22) Filed: Dec. 18, 2021

(30) Foreign Application Priority Data
Dec. 19, 2020 (CN) 202011509788.0

(51) Int. Cl. H05K 5/02; B29C 45/00; B29C 45/14

(52) U.S. Cl. CPC H05K 5/02; B29C 45/0005; B29K 2705/00; B29C 45/14; B29C 45/0053

(57) ABSTRACT

A housing and a method for processing the housing, the housing includes a first surface, the first surface includes a filler area with a first length, the method includes: providing a metal piece including a groove and a second surface, the groove includes a groove bottom, the groove bottom defines a recess extending through the groove bottom and the second surface, the recess has a second length, the second length is greater than or equal to the first length; injecting filling liquid into the recess and the groove, the filling liquid solidified to form the filler of the filler area; and cutting the metal piece along the second surface to form the first surface of the housing.

### CROSS-REFERENCE TO RELATED APPLICATIONS

This application claims priority to Chinese Patent Application No. 202011509788.0 filed on Dec. 19, 2020, the contents of which are incorporated by reference herein.

### FIELD

The subject matter herein generally relates to manufacturing processes, and particularly to a housing and a method for processing a housing.

### BACKGROUND

In the field of manufacturing and processing, metal frames for being a housing of electronic devices can improve a texture. At least one part of the metal frame servers as an antenna, the metal frame defines at least one split, which being filled with plastic for forming a non-closing metal structure to prevent affection of signal transmission of the antenna. However, the metal frame is normally processed by cutting, glass fibers of the plastic in the metal frame may easily fall off when the metal frame being cutting, which may cause a visual failure or a poor appearance.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 illustrates a schematic diagram of at least one embodiment of a housing.

FIG. 2 illustrates a schematic view of at least one embodiment of a metal piece.

FIG. 3 illustrates a schematic view of at least one embodiment of an injection molding of the metal piece of FIG. 2.

FIG. 4 illustrates a schematic of at least one embodiment of a cutting of the metal piece of FIG. 3.

FIG. 5 illustrates a flowchart of at least one embodiment of a method for processing a housing.

### DETAILED DESCRIPTION

Implementations of the disclosure will now be described, by way of embodiments only, with reference to the drawings. The disclosure is illustrative only, and changes may be made in the detail within the principles of the present disclosure. It will, therefore, be appreciated that the embodiments may be modified within the scope of the claims.

Unless otherwise defined, all technical terms used herein have the same meaning as commonly understood by one of ordinary skill in the art. The technical terms used herein are to provide a thorough understanding of the embodiments described herein but are not to be considered as limiting the scope of the embodiments.

Several definitions that apply throughout this disclosure will now be presented.

The term “coupled” is defined as connected, whether directly or indirectly through intervening components, and is not necessarily limited to physical connections. The term “substantially” is defined to be essentially conforming to the particular dimension, shape or other word that the term modifies, such that the component need not be exact. The term “comprising,” when utilized, means “including, but not necessarily limited to”; it specifically indicates open-ended inclusion or membership in the so-described combination, group, series and the like.

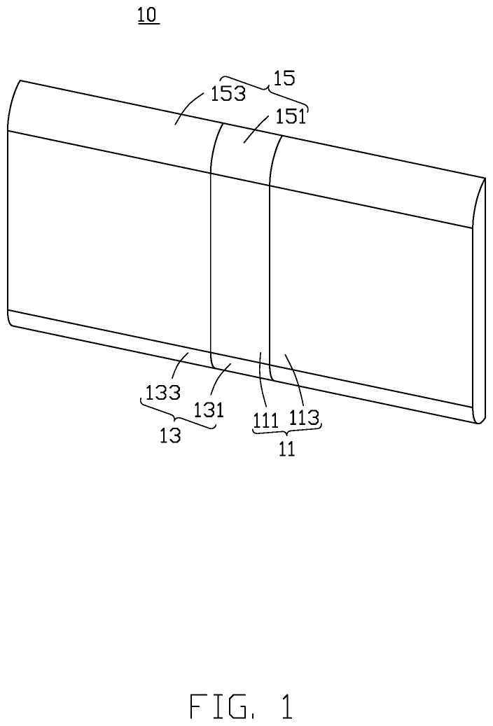

FIG. 1 illustrates a schematic diagram of at least one embodiment of a housing 10. The housing 10 may be servers as a frame of an electronic device. The electronic device may be a cellphone, a tablet computer, a laptop computer, a personal digital assistant (PDA), a wearable electronic device, an augmented reality (AR) device, a virtual reality (VR) device.

The housing 10 includes a first surface 11, a third surface 13, and a fourth surface 15. The third surface 13 and the fourth surface 15 are connected to opposite sides of the first surface 11. In at least one embodiment, the first surface 11 is a plane, the third surface 13 and the fourth surface 15 are curved surfaces. In other embodiments, the first surface 11 is a curved surface, the third surface 13 and the fourth surface 15 are plane surfaces.

The first surface 11 includes a filler area 111 and a metal area 113 on opposite sides of the filler area 111. A material of the metal area 113 may be metal or metal composite material, the metal may include aluminum, magnesium, stainless steel, titanium and titanium alloys, etc. The filler area 111 is filled by filler, a material of the filler area 111 may be at least one of plastic, ceram, resin, and other organic matters. The filler may be formed by solidifying a filling liquid including fibers, which may speed up the solidifying and improve a combination strength. The fibers include at least one of carbon fibers, glass fibers, and aramid fibers. In at least one embodiment, the filler may include plastic, the plastic may include glass fibers, or the plastic material may be mixed with glass fibers. In the filler area 111, the glass fibers may be arranged in one direction and perpendicularly to the first surface 11, which may prevent a falling off the glass fibers that causing a visual failure or a poor appearance. In at least one embodiment, the arrangement direction of the glass fibers indicates a flow direction of the filling liquid.

Selectively, the filler area 111 includes a first length within a range about 1-6 millimeters and a width within a range about 0.5-5 millimeters. A direction from the first surface 11 extending to the third surface 13 or the fourth surface 15 is defined as a first direction. A direction of the first length is parallel to the first direction. In at least one embodiment, the first length may be a width of the first surface 11 between the third surface 13 and the fourth surface 15. When the first surface 11 is a plane, the first length is a linear length; when the first surface 11 is a curved surface, the first length is an arc length of the first surface 11 cut by a plane that from the first surface to the third surface.

The third surface 13 includes a filler area 131 and a metal area 133 on opposite sides of the filler area 131. The filler area 131 of the third surface 13 is aligned to the filler area 111 of the first surface 11. The metal area 133 of the third surface 13 is aligned to the metal area 113 of the first surface 11.

The fourth surface 15 includes a filler area 151 and a metal area 153 on opposite sides of the filler area 151. The filler area 151 of the fourth surface 15 is aligned to the filler area 111 of the first surface 11. The metal area 153 of the fourth surface 15 is aligned to the metal area 113 of the first surface 11.

Materials of the housing 10 for the filler area 131 of the third surface 13 and the filler area 151 of the fourth surface 15 may be at least one of plastic, ceram, resin, and other organic matters. Materials of the housing 10 for the metal area 133 of the third surface 13 and the metal area 153 of the fourth surface 15 may be metal or metal composite material.

Selectively, the third surface 13 and the fourth surface 15 may only include the metal area, the filler corresponding to the filler area 111 may be filled in holes defined in the metal area.

In at least one embodiment, in the housing 10, the filler is cut by a plane parallel to the first surface and forms a section, the section may be dull polished (such as dull polished by a grinding wheel), observed by a microscope, such as a scanning electron microscope (SEM), an arranging direction of at least one fiber in the section is perpendicular to the first surface 11. Preferably, an arranging direction of at least 80% of the fibers in the section is perpendicular to the first surface 11, thus when the housing 10 is cut, the fibers may be a spotty pattern in the cutting surface, thereby the filler area of the first surface 11 of the housing 10 after cutting is intact without fibers falling off.

For instance, when the filler is plastic, the fibers may be glass fibers, the filling liquid may be injection liquid including glass fibers. Injecting the injection liquid into the slot, due to an injecting direction of the injection liquid is consistent, an arranging direction of the glass fibers in the slot is consistent, at least 80% of the glass fibers are perpendicular to the first surface 11, thereby the first surface 11 of the housing 10 after cutting is intact without glass fibers falling off.

In at least one embodiment, a method for processing the housing is provided.

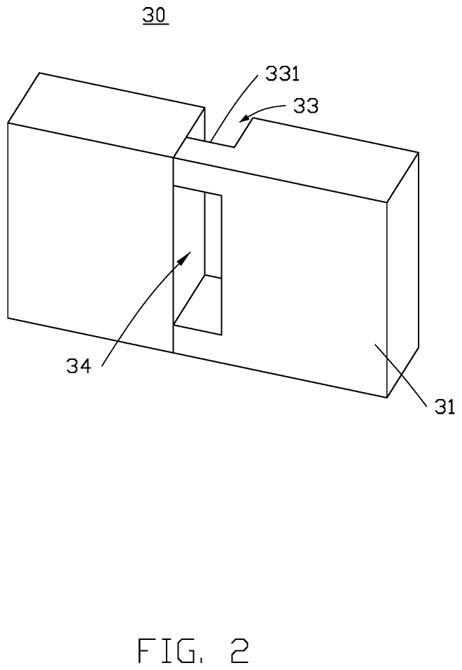

Referring to FIG. 2, providing a metal piece 30, the metal piece 30 includes a second surface 31. The metal piece 30 defines a groove 33 on a side opposite to the second surface 31 (an opening direction of the groove 33 is opposite to the second surface 31). The groove 33 includes a groove bottom 331, the groove bottom 331 defines a recess 34 extending through the groove bottom 331 and the second surface 31.

The recess 34 has a second length. A direction of the second length is parallel to the direction of the first length of the filler area 111 of the first surface 11. The second length is greater than the first length. The groove 33 has a third length. A direction of the third length is parallel to the direction of the first length, the third length is greater than or equal to the first length.

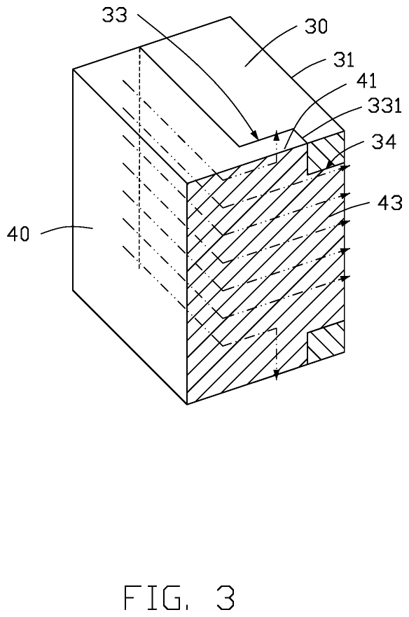

Referring to FIG. 3, injecting filling liquid into the recess 34 and the groove 33, the filling liquid is solidified to form the filler 40.

An imaginary line shown in FIG. 3 shows an injecting direction, the filling liquid is injected along a side of the metal piece 30 opposite to the second surface 31 to the recess 34 and the groove 33. The filling liquid includes injection liquid including glass fibers. An arranging direction of the glass fibers is same with the injecting direction (or flow direction) of the filling liquid. In other embodiments, the filling liquid may be solidified as ceramic solution.

When injecting the filling liquid into the recess 34 and an area of the groove 33 corresponding to the recess 34, the injection direction of the filling liquid in the recess 34 is perpendicular to the second surface 31, the arranging direction of the glass fibers is perpendicular to the second surface 31. When injecting the filling liquid into an area of groove 33 non-corresponding to the recess 34, due to a resist of groove bottom 331, the filling liquid is injected in a direction parallel to the second surface 31, thus an arranging direction of the glass fibers is substantially parallel to the second surface 31.

The filler 40 includes a first filling portion 41 in the groove 33 and a second filling portion 43 in the recess 34. Along the direction of the second length, the first filling portion 41 includes opposite ends.

An arranging direction of the glass fibers in a part of the first filling portion 41 corresponding to the recess 34 is perpendicular to the second surface 31. An arranging direction of the glass fibers in a part of the first filling portion 41 non-corresponding to the recess 34 is parallel to the second surface 31. The glass fibers in the second filling portion 43 is perpendicular to the second surface 31.

In at least one embodiment, the second length of the recess 34 is greater than or equal to the first length of the filler area 111, which is for cutting the filler in the recess 34 to form the filler area 111, due to an arranging direction of the glass fibers in the recess 34 is consistent, which may prevent glass fibers falling off. If the second length of the recess 34 is smaller than the first length of the filler area 111, the injecting direction of the filling liquid in the groove 33 is not consistent, thus the arranging direction of the glass fibers in the groove 33 is not consistent, when being cut, which may cause glass fibers fall off and bad appearance of the housing.

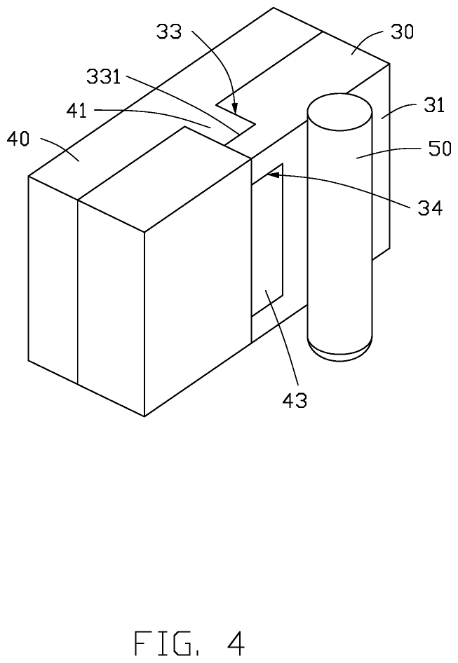

Referring to FIG. 4, cutting the metal piece 30 along the second surface 31 to form the first surface 11 of the housing 10.

The metal piece 30 is cut to form the metal area 113 of the first surface 11. A cutting thickness along the second surface 31 is smaller than a thickness of the metal piece 30. When the cutting thickness along the second surface 31 is smaller than a liner distance between the groove bottom 331 and the second surface 31, due to the second length of the recess 34 is greater than or equal to the first length of the filler area 111, at least a part of the second filling portion 43 is cut and forms the filler area 111. When the cutting thickness along the second surface 31 is greater than or equal to the liner distance between the groove bottom 331 and the second surface 31, due to the third length of the groove 33 is greater than the first length of the filler area 111, at least a part of the first filling portion 41 corresponding to the recess 34 is cut and forms the filler area 111 of the first surface 11. Due to the arranging direction of the glass fibers in the recess 34 and the area of the groove 33 corresponding to the recess 34 is perpendicular to the second surface 31, that is the glass fibers in the recess is arranged in a same direction, thus the glass fibers may not fall off when being cut by a knife, which may prevent glass fibers falling off and a good appearance of the housing. In at least one embodiment, the method for processing the housing 10 further includes cutting the second surface 31 to expose the first filling portion 41, and cutting the first filling portion 41 on opposite ends to form the third surface 13 and the fourth surface 15.

In at least one embodiment, the cutting includes cutting the metal piece 30 by a knife 50, a cutting direction of the knife 50 is perpendicular to the injecting direction of the filling liquid.

Selectively, a rotate speed of the knife 50 may be 8000˜12000 r/min. The knife 50 may have a matching shape with the first surface 11, the third surface 13, and the fourth surface 15 of the housing.

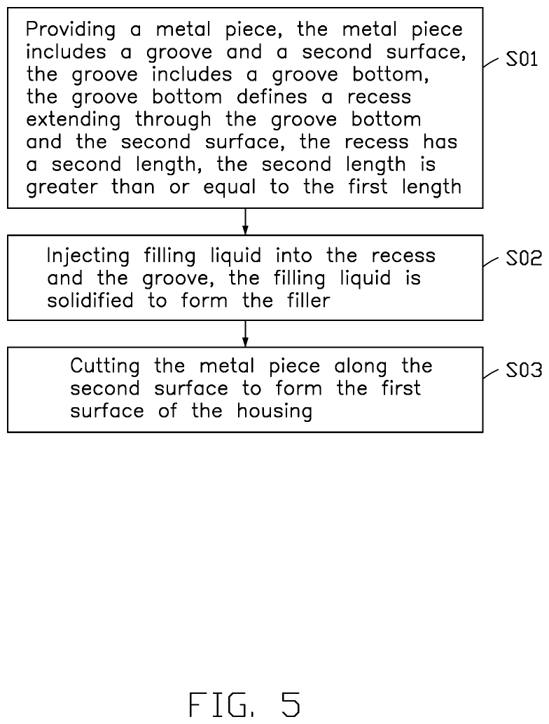

FIG. 5 illustrates a flowchart of at least one embodiment of a method for processing the housing. The housing includes a first surface, the first surface includes a filler area, the filler area has a first length. The method includes:

At block S01, providing a metal piece, the metal piece includes a groove and a second surface, the groove includes a groove bottom, the groove bottom defines a recess extending through the groove bottom and the second surface, the recess has a second length, the second length is greater than or equal to the first length.

The housing includes a first surface, a third surface, and a fourth surface. The third surface and the fourth surface are connected to opposite sides of the first surface. In at least one embodiment, the first surface is a plane, the third surface and the fourth surface are curved surfaces. In other embodiments, the first surface is a curved surface, the third surface and the fourth surface are plane surfaces.

The filler area includes a first length within a range about 1-6 millimeters and a width within a range about 0.5-5 millimeters. A direction from the first surface extending to the third surface or the fourth surface is defined as a first direction. A direction of the first length is parallel to the first direction. In at least one embodiment, the first length may be a width of the first surface between the third surface and the fourth surface. When the first surface is a plane, the first length is a linear length; when the first surface is a curved surface, the first length is an arc length of the first surface cut by a plane that from the first surface to the third surface.

A direction of the second length is parallel to the direction of the first length of the filler area of the first surface. The second length is greater than or equal to the first length. The groove has a third length. A direction of the third length is parallel to the direction of the first length, the third length is greater than or equal to the first length.

At block S02, injecting filling liquid into the recess and the groove, the filling liquid is solidified to form the filler.

The filling liquid is injected along a side of the metal piece opposite to the second surface to the recess and the groove. The filling liquid includes injection liquid including glass fibers. An arranging direction of the glass fibers is same with the injecting direction (or flow direction) of the filling liquid. When injecting the filling liquid into the recess and an area of the groove corresponding to the recess, the injection direction of the filling liquid in the recess is perpendicular to the second surface, the arranging direction of the glass fibers is perpendicular to the second surface. When injecting the filling liquid into an area of groove non-corresponding to the recess, due to a resist of groove bottom, the filling liquid is injected in a direction parallel to the second surface, thus an arranging direction of the glass fibers is substantially parallel to the second surface.

The filler includes a first filling portion in the groove and a second filling portion in the recess. Along the direction of the second length, the first filling portion includes opposite ends.

An arranging direction of the glass fibers in a part of the first filling portion corresponding to the recess is perpendicular to the second surface. An arranging direction of the glass fibers in a part of the first filling portion non-corresponding to the recess is parallel to the second surface. The glass fibers in the second filling portion is perpendicular to the second surface.

At block S03, cutting the metal piece along the second surface to form the first surface of the housing.

The metal piece is cut to form the metal area of the first surface. A cutting thickness along the second surface is smaller than a thickness of the metal piece. When the cutting thickness along the second surface is smaller than a liner distance between the groove bottom and the second surface, due to the second length of the recess is greater than or equal to the first length of the filler area, at least a part of the second filling portion is cut and forms the filler area. When the cutting thickness along the second surface is greater than the liner distance between the groove bottom and the second surface, due to the third length of the groove is greater than or equal to the first length of the filler area, at least a part of the first filling portion corresponding to the recess is cut and forms the filler area of the first surface. Due to the arranging direction of the glass fibers in the recess and the area of the groove corresponding to the recess is perpendicular to the second surface, that is the glass fibers in the recess is arranged in a same direction, thus the glass fibers may not fall off when being cut by a knife, which may prevent glass fibers falling off and a good appearance of the housing is obtained.

The method for processing the housing further includes cutting the second surface to expose the first filling portion, and cutting the first filling portion on opposite ends to form the third surface and the fourth surface.

In at least one embodiment, the cutting includes cutting the metal piece by a knife, a cutting direction of the knife is perpendicular to the injecting direction of the filling liquid, thus a tangential direction of any point of the first surface formed after cutting is perpendicular to the injecting direction of the filling liquid, which may prevent glass fibers of the filling portions of the first surface falling off.

Selectively, a rotate speed of the knife 50 may be 8000˜12000 r/min. With the rotate speed of the knife 50, a small roughness of the first surface after cutting may be obtained.

The method for processing the housing defines the groove with a length greater than or equal to a length of the filler area of the first surface, injects filling liquid including glass fibers into the recess, thus the arranging direction of the glass fibers in the recess is consistent and perpendicular to the second surface, when cutting the metal piece along the second surface to form the first surface, the glass fibers may not fall off when being cut by the knife, which may prevent glass fibers falling off and a good appearance of the housing is obtained.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure as defined by the appended claims.

What is claimed is:

1. A method for processing a housing, the housing comprises a first surface, the first surface comprises a filler area with a first length, the method comprising:
providing a metal piece, wherein the metal piece comprises a groove and a second surface, the groove comprises a groove bottom, the groove bottom defines a recess extending through the groove bottom and the second surface, the recess has a second length, the second length is greater than or equal to the first length;
injecting filling liquid into the recess and the groove, the filling liquid solidified to form filler of the filler area; and
cutting the metal piece along the second surface to form the first surface of the housing.

2. The method according to claim 1, wherein a cutting thickness along the second surface is greater than or equal to a liner distance between the groove bottom and the second surface.

3. The method according to claim 2, wherein the cutting thickness along the second surface is smaller than a thickness of the metal piece.

4. The method according to claim 1, wherein the groove has a third length, a direction of the third length is parallel to a direction of the first length, the third length is greater than the first length.

5. The method according to claim 1, wherein the housing further comprises a third surface and a fourth surface, the third surface and the fourth surface are connected to opposite sides of the first surface, the filler comprises a first filling portion in the groove, along a direction of the second length, the first filling portion comprises opposite ends.

6. The method according to claim 5, further comprising:
cutting the second surface to expose the first filling portion; and
cutting the first filling portion on opposite ends to form the third surface and the fourth surface.

7. The method according to claim 5, wherein the first surface is a plane, the third surface and the fourth surface are curved surfaces.

8. The method according to claim 1, wherein a range of the first length is 1-6 millimeters.

9. The method according to claim 1, wherein a range of a width of the filler area is 0.5-5 millimeters.

10. A housing comprising a first surface, the first surface comprises:
a filler area; and
a metal area positions on opposite sides of the filler area;
wherein the filler area is filled by filler, which comprises fibers, an arranging direction of at least one of the fibers is perpendicular to the first surface.

11. The housing according to claim 10, wherein a range of a length of the filler area is 1-6 millimeters, a range of a width of the filler area is 0.5-5 millimeters.

12. The housing according to claim 10, wherein the filler area is a plastic area, the filler is formed by solidifying injection liquid, the fibers are glass fibers.

13. The housing according to claim 10, wherein an arranging direction of at least 80% of the fibers is perpendicular to the first surface.

14. The housing according to claim 10, further comprising a third surface and a fourth surface, wherein the third surface and the fourth surface are connected to opposite sides of the first surface.

15. The housing according to claim 14, wherein the first surface is a plane, the third surface and the fourth surface are curved surfaces.
